(19) United States
(12) Patent Application Publication
(10) Pub. No.: US 2019/0003036 A1
(43) Pub. Date: Jan. 3, 2019

(54) STRUCTURED COATING SOURCE

(71) Applicant: PLANSEE COMPOSITE MATERIALS GMBH, LECHBRUCK AM SEE (DE)

(72) Inventors: PETER POLCIK, REUTTE (AT); SABINE WOERLE, PFLACH (AT); RONNIE INNERWINKLER, WISSENBACH (AT)

(21) Appl. No.: 16/061,688

(22) PCT Filed: Dec. 7, 2016
(86) PCT No.: PCT/EP2016/002059

§ 371 Date: Jun. 13, 2018

(30) Foreign Application Priority Data
Dec. 18, 2015 (AT) GM 371/2015

(51) Int. Cl. C23C 14/34; C23C 14/06

(52) U.S. Cl. CPC C23C 14/3414; C23C 14/0635; C23C 14/067

(57) ABSTRACT

A coating source for physical vapor deposition has a coating material which consists of a brittle material and has cracks. The coating source additionally has a support element which is joined to the coating material at a surface of the coating material. Furthermore, the coating material has structuring on at least parts of a surface of the coating material. There is also described a process for producing a coating source.

The invention relates to a coating source for physical vapor deposition and also a process for producing a coating source for physical vapor deposition.

In physical vapor deposition (PVD), starting material is brought into the vapor phase by physical processes and subsequently deposited on a substrate to be coated.

In the context of the present disclosure, the term coating source encompasses not only but in particular coating sources (often also referred to overall as target or sputtering target) as are used in a PVD sputtering process (cathode atomisation) for deposition of layers on a substrate material provided for this purpose.

Coating sources which contain brittle materials or consist of brittle materials constitute a particularly great challenge both in the use of the coating source during the coating process and also in the production of the coating source itself.

Thus, machining of such coating sources or components thereof during their production, which can, for example, be made necessary by complicated geometries which may be required for installation in different coating plants, is often difficult to carry out. Such machining can often be achieved only by grinding and wire erosion but not by cutting machining. This means that only simple geometries (rounds, plates, rings) can be manufactured and high costs are incurred by the machining process.

Particularly good cooling is required, especially when high powers or high power densities are applied, in order to avoid thermally induced stresses which can lead to rupture of the coating source or components thereof, e.g. the coating material. Efficient cooling of such coating sources during the coating process is usually made possible by means of cooling water. The coating sources are cooled via cooling plates which are arranged on the rear side of the coating sources. These cooling plates are in turn cooled by the cooling water which removes the heat evolved during the coating process.

Particularly in the case of flexible, elastic cooling plates, mechanical stress is exercised on the coating source, which can in turn lead to plastic deformation of the coating source or to fracture. This effect is additionally reinforced by the thickness of the coating source, in particular of the coating material, being reduced during the coating process. This has the consequence that it is even more probable that deformation and/or fracture can occur.

It is therefore usual to provide, in particular, coating sources which contain brittle materials with support elements, for example back plates or support tubes, during construction.

Such a support element can additionally serve as heat sink, i.e. the heat evolved in the coating process can be removed better by application of a support element having a thermal conductivity which is higher than that of the coating material. In such a case, the total arrangement of coating material and support element which can also serve as heat sink is referred to as coating source.

Such support elements/heat sinks having higher strength and stiffness can be applied by means of various processes to coating materials having a low toughness (brittle materials behavior). In the case of a significant difference between the coefficients of thermal expansion of support elements/heat sink and coating material, formation of cracks in the coating material or fracture of the coating material can occur during the coating process.

JP62278261 describes a process in which cracks are deliberately introduced into a brittle coating material after a joining step by means of indium bonding in order to prevent crack formation during the coating process itself. This ensures a more stable coating process.

PCT/EP2015/001298 describes a process in which cracks are likewise deliberately introduced into a brittle coating material after a joining step by means of brazing in order to make a more stable sputtering process possible subsequently. Here, the cracks are formed during cooling from the temperature of brazing or crack formation is subsequently assisted by a particle blasting process. For this crack formation to take place, the coefficient of expansion of the support element/the heat sink has to be lower than that of the coating material.

In both the processes mentioned, the formation of the cracks is random and spalling of small pieces of the coating material can occur.

It is an object of the present invention to provide a coating source which is improved relative to the prior art and also a process for producing such a coating source by physical vapor deposition.

These objects are achieved by a coating source having the features of claim 1 and also a process having the features of claim 13. Advantageous embodiments of the invention are defined in the dependent claims.

The invention provides a coating source for physical vapor deposition which comprises a coating material which consists of a brittle material and has cracks. Furthermore, the coating source has a support element which is joined to it at a surface of the coating material. The coating material of the coating source of the invention additionally has structuring on at least parts of a surface of the coating material.

For the present purposes, a brittle material is a material which fractures close to the elastic limit without plastic deformation or with only little plastic deformation. These materials and thus also the sputtering targets produced therefrom therefore have only a low plastic deformation capability. The elongation at break of brittle materials is typically less than or equal to 1%. Furthermore, brittle materials have a low toughness and thus display only a small resistance to crack formation and crack propagation. Examples of such brittle materials are ceramic materials, in particular borides, nitrides, carbides, silicides, oxides, and also metallic brittle materials such as Cr or Si or intermetallic compounds such as Ti₃Al or TiAl₃ and also mixtures of these materials.

The structuring of a coating source according to the invention can be different. Thus, the structuring can, for example, consist of depressions, grooves, notches or slits which can be introduced in various ways into at least parts of a surface of the coating material.

The coating material itself can be made up of one or more parts. If the coating material is made up of a plurality of parts, the structuring can have been introduced into all parts or only into some of the parts of the coating material.

The shape or cross section of these depressions, grooves, notches or slits can likewise be different. Thus, the cross section can, for example, have the shape of a semicircle, a rectangle, a square, a triangle or a trapezium.

The depth of the structuring, i.e. its spatial extension in the direction of the thickness of the coating source, is preferably in the range from 0.1 to 5 mm. The depth of the structuring can also be greater in particular cases, but it should be ensured that at least 1 mm of coating material remains in the depth direction.

The width of the structuring, i.e. its spatial extension perpendicular to the direction of the depressions, grooves, notches, slits, etc., is preferably in the range from 0.1 to 2 mm, preferably from 0.1 to 1 mm.

The cracks preferably run largely along the structuring, meaning that the cracks in the structuring or in the vicinity of the structuring run largely parallel thereto. For the purposes of the present invention, largely parallel means a crack direction deviating by up to a maximum of 20°, preferably up to a maximum of 10°, from the direction of the structuring. The spread of the cracks therefore has a clearly recognisable relationship to the structuring or to the arrangement of the structuring. Thus, the cracks run, over a predominant part of the total crack length, in the structuring or mostly parallel to the structuring or with a small angle of inclination thereto. The cracks thus occur in a pattern which largely follows the structuring or the arrangement of the structuring.

As a result of the structuring, the cracks do not run randomly but instead preferably follow the structuring in their spread. The cracks are formed in an at least largely controlled manner and the size of the individual crack-free regions of the coating material (fragments) is at least largely predefined. Spalling of smaller pieces of the coating material therefore cannot occur or can occur only to a small extent. It can therefore be ensured when using the coating source that neither the coating plant nor the deposited layer is contaminated or damaged by pieces which have broken off in this way.

A proportion of more than 50% of the total crack length of the cracks preferably runs along the structuring. This ensures even greater process reliability when using a coating source according to the invention.

The depth (spatial extension in the direction of the thickness of the coating source) of the cracks preferably extends completely through the coating material. Thus, there is preferably complete parting of the material between the individual fragments of the coating material.

The structuring is preferably present on the surface of the coating material facing away from the support element. In the production of the coating source, a higher tensile stress arises on the surface of the coating material facing away from the support element than on the surface facing the support element (the latter surface is closer to the neutral fibre of the coating source stressed in flexure). As a result of structuring, crack formation in the brittle coating material therefore takes place more reliably and reproducibly on the surface of the coating material facing away from the support element.

However, it is also possible for the structuring to be present on the surface of the coating material facing the support element. Such an embodiment can offer advantages in the case of particularly brittle coating materials and at specific ratios between the thickness of the coating material d₂ and the thickness of the support element d₃ since the cracks formed are in such cases particularly fine (small distance between the sides of the cracks) and the comparatively coarsely (width of the individual depressions, grooves, notches, etc.) introduced structuring is not visible.

The structuring can, in a particular embodiment, consist of an arrangement of a first group of parallel linear depressions and a second group of parallel linear depressions which are arranged at an angle of from 70° to 110° to the first group of parallel linear depressions. Such an arrangement is easy to realise in process engineering terms and the distances between the respective linear depressions can easily be matched to the dimensions of the coating source and to the difference between the coefficients of thermal expansion of the coating material and of the support element and consequently the resulting stresses. Furthermore, no excessively acute angles and therefore no unfavourable stress concentrations arise due to arrangement of the groups of depressions at an angle of from 70° to 110° relative to one another.

In a further preferred embodiment, the structuring consists of an arrangement of a first group of parallel linear depressions and a second group of parallel linear depressions which are arranged at right angles to the first group of parallel linear depressions. In such an arrangement, unfavourable stress concentrations are avoided to an even greater extent.

As an alternative, the structuring can also be present in other geometric arrangements, for example in the form of concentric circles which can optionally have a star-shaped arrangement of lines superimposed on them. A spiral arrangement instead of the concentric circles is also conceivable.

The coefficient of thermal expansion of the coating material α₂ is preferably greater than the coefficient of thermal expansion of the support element α₃. In the production of the coating source, which usually comprises at least one process step at elevated temperatures, such a ratio of the coefficients of thermal expansion preferably results in the coating material contracting to a greater extent on cooling from the elevated temperature than the support element and a tensile stress being introduced into the coating material, which in turn leads to particularly reliable and reproducible formation of the cracks. The greater the difference between the coefficient of thermal expansion of the coating material α₂ and that of the support element α₃, the greater the absolute value of the stresses introduced.

A coating source according to the invention can have a coating material composed of different brittle materials. Thus, it is possible for the coating material to consist of carbides (e.g.: TiC, SiC, WC), borides (e.g.: TiB₂, VB₂, CrB₂), nitrides (e.g.: TiN, AlN, TiNAlN), silicides (e.g.: TiSi₂, CrSi₂, MoSi₂), oxides (e.g.: Al₂O₃, (Al,Cr)₂O₃), brittle metals (e.g.: Cr, Si), intermetallic phases (e.g.: Ti₃Al, TiAl₃, Al₄Cr) or else mixtures of the abovementioned materials. As a result of the structuring, it is readily possible to make a coating source having a coating material composed of a brittle material and to operate the coating source even at high power densities.

A coating source according to the invention preferably has a coating material which consists of TiB₂, SiC, B₄C, MoSiB or CrSiB. It has been found that in the case of these coating materials, structuring can be introduced particularly readily and the cracks run in a particularly uniform manner.

A coating source according to the invention also preferably has a support element composed of molybdenum, tungsten, tantalum, a molybdenum-based alloy, a tungsten-based alloy or a tantalum-based alloy. Molybdenum-based alloys, tungsten-based alloys and tantalum-based alloys are in the present case alloys or composite materials which respectively contain more than 50 at % of molybdenum, tungsten or tantalum. Molybdenum, tungsten, tantalum, molybdenum-based alloys, tungsten-based alloys or tantalum-based alloys are particularly suitable for use in a support element of this type also because they have a particularly advantageous property combination of a sufficiently high thermal conductivity, a high E modulus, i.e. a high stiffness, and a relatively low coefficient of thermal expansion.

In particularly preferred embodiments, the E modulus of the support element E₃ is greater than or equal to 300 GPa. The E modulus of the support element is even more preferably less than 500 GPa.

For economic reasons, the ratio X=d₂/(d₂+d₃) is made as high as is technically possible, viz. the thickness of the coating material d₂ makes up a large proportion of the total thickness of the coating source d₁=d₂+d₃.

It has, however, surprisingly been found that deliberate introduction of cracks without structuring, as described in the prior art, only functions well in the case of coating sources in which the coating material has a thickness comparable to or lower than that of the support element. In the case of coating materials which are too thick relative to the support element, permanent bending of the support element occurs instead of crack formation in the coating material during production of the coating source. It is presumed that in such cases the tensile stresses in the coating material are lower than the fracture stress of the coating material. Coating sources which have been deformed (bent) in this way can firstly no longer be installed correctly in a coating plant. Secondly, a coating source which has been deformed in this way would suddenly rupture on attainment of the critical stress and in turn lead to disruption of the coating process due to the progressive removal of material during the coating process and the decreasing thickness of the coating material associated therewith.

A coating source according to the invention preferably has a ratio X=d₂/(d₂+d₃) of the thickness of the coating material d₂ to the sum d₂+d₃ of the thickness of the coating material d₂ and the thickness of the support element d₃ of greater than 0.5. A maximum ratio X of 0.9 is appropriately even more preferred.

A coating source according to the invention even more preferably has a ratio X=d₂/(d₂+d₃) of the thickness of the coating material d₂ to the sum d₂+d₃ of the thickness of the coating material d₂ and the thickness of the support element d₃ of greater than or equal to 0.6. A maximum ratio X of 0.85 is appropriately even more preferred.

Coating sources according to the invention can be either plate-shaped or tubular; deliberate crack introduction along structuring is possible for both types of coating sources and has the advantage that the cracks do not run randomly but their spread preferably follows the structuring. For this reason, relatively small pieces of the coating material, and thus the coating source, cannot break away or break away to only a small extent, as described above.

In one preferred embodiment, the coating source is plate-shaped. In such a case, the support element is configured as back plate. Owing to the complex stress states which arise in such a coating source according to the invention during the production thereof, the deliberate introduction of cracks along structuring can be achieved very readily in a plate-shaped coating source.

As an alternative, an embodiment in which the coating source is tubular is preferred. In such a case, the support element is configured as support tube or carrier tube. In the case of a tubular coating source, too, similar criteria and prerequisites which promote targeted spread of cracks as a result of the introduction of structuring are present. In the case of a tubular coating source, it is also particularly advantageous for the coefficient of thermal expansion of the coating material α₂ to be greater than the coefficient of thermal expansion of the support element (support or carrier tube) α₃.

The present invention also provides a process for producing a coating source for physical vapor deposition.

Such a process comprises the following steps:
provision of a coating material which consists of a brittle material;
structuring of the coating material to produce structuring on at least parts of a surface of the coating material;
provision of a support element;
joining of the coating material to the support element;
introduction of cracks into the coating material.

A process according to the invention makes it possible to fabricate a coating source which contains a coating material composed of a brittle material and a support element, which are joined to one another. The coating material is structured and cracks are introduced into the coating material by the process of the invention.

For the present purposes, a brittle material is a material which fractures close to the elastic limit without plastic deformation or with only little plastic deformation. These materials and thus also the sputtering targets produced therefrom therefore have only a low plastic deformation capability. The elongation at break of brittle materials is typically less than or equal to 1%. Furthermore, brittle materials have a low toughness and thus display only a small resistance to crack formation and crack propagation. Examples of such brittle materials are ceramic materials, in particular borides, nitrides, carbides, silicides, oxides, and also metallic brittle materials such as Cr or Si or intermetallic compounds such as Ti₃Al or TiAl₃ and also mixtures of these materials.

The structuring of the coating material to produce structuring can be achieved by means of various processes. In a preferred embodiment of the process, the structuring of the coating material is effected by erosion, wire cutting, grinding or parting. Here, for example, depressions, grooves, notches or slits, which can represent different geometric arrangements, are introduced into at least parts of a surface of the coating material.

As an alternative, preference is given to structuring of the coating material by pressing-in of a profiled pressing tool. Such pressing in of structuring by means of a profiled pressing tool can, for example, take place during powder-metallurgical production of the coating material itself. Here, the profiled pressing tool can be configured either as upper punch or lower punch in an appropriate pressing apparatus. However, it is also possible for a predensified or fully densified blank of a coating material to be structured separately by pressing-in of a profiled pressing tool. Furthermore, it is possible for the upper or lower punch not to be profiled itself, but instead for a profiled intermediate plate to be laid on or under the powder bed or the predensified or fully densified blank.

Regardless of the way in which structuring is effected, different geometric arrangements of structuring can be achieved thereby. Thus, the structuring operation can produce an arrangement of a first group of parallel linear depressions and a second group of parallel linear depressions which are arranged at an angle of from 70° to 110° to the first group of parallel linear depressions. Such an arrangement is easy to achieve in process engineering terms and the distances between the respective linear depressions can easily be matched to the dimensions of the coating source and to the difference between the coefficient of thermal expansion of the coating material and that of the support element and consequently the resulting stresses. Such an arrangement can be particularly advantageously produced by erosion, wire cutting, grinding or parting, but also by pressing-in of a profiled pressing tool.

Preference is also given to the structuring operation producing an arrangement of a first group of parallel linear depressions and a second group of parallel linear depressions which are arranged at right angles to the first group of parallel linear depressions. In the case of such an arrangement, unfavourable stress concentrations are avoided to an even greater extent.

As an alternative, the structuring operation can also produce other geometric arrangements, for example a form of concentric circles, on which a star-shaped arrangement of lines can optionally be superimposed. A spiral arrangement instead of the concentric circles is also conceivable. Such an arrangement can be particularly advantageously produced by pressing-in of a profiled pressing tool.

In a particularly advantageous embodiment of the process of the invention, the structuring of the coating material to produce structuring is introduced at at least parts of the surface of the coating material which, after joining to the support element, are present on the surface of the coating material facing away from the support element.

When the process is employed for producing a coating source, a higher tensile stress arises on the surface of the coating material facing away from the support element than on the surface facing the support element (the latter surface is closer to the neutral fibre). As a result of structuring on the surface of the coating material facing away from the support element, crack formation in the brittle coating material therefore takes place more reliably and reproducibly.

However, it is also possible to carry out structuring on the surface of the coating material facing the support element. Such a process step can offer advantages in the case of particularly brittle coating materials and in the case of specific ratios between the thickness of the coating material d₂ and the thickness of the support element d₃, since in such cases the cracks formed are particularly fine (smaller distance between the sides of the cracks) and the comparatively coarsely introduced structuring (width of individual depressions, grooves, notches, etc.) is not visible.

Joining of the coating material to the support element can likewise be effected in different ways. Joining of the coating material to the support element preferably takes place at temperatures of more than 100° C. and less than 1000° C.

In a further preferred embodiment of the process, joining of the coating material to the support element is effected by brazing at temperatures in the range from 400° C. to 950° C. Brazing in this temperature range makes it possible to achieve excellent thermal stability of the coating source, which allows the coating source to be operated at particularly high power densities and thus high deposition rates in the coating process. During a coating process, the coating chamber is normally heated to temperatures in the order of 400° C. However, the coating source is not entirely subjected to these temperatures since it is additionally cooled from the rear side. Joining at temperatures in the range from 400° C. to 950° C. can ensure that the coating source has already been subjected to similar thermal stresses as occur during the coating process and can thus no longer experience damage resulting therefrom. Joining at temperatures in the range from 400° C. to 950° C. also has the consequence that the difference between the coefficient of thermal expansion of the coating material and that of the support element results in correspondingly high stresses, preferably tensile stresses, which in turn promote the formation of the cracks.

Particular preference is given to the introduction of the cracks taking place as a result of cooling from an elevated temperature. In the present case, elevated temperatures are temperatures of more than 100° C. and less than 1000° C., which are preferably attained during joining of the coating material to the support element. However, it is also possible for further heating to an elevated temperature to be carried out after joining and the introduction of cracks then occurs during cooling from this elevated temperature.

It is even more preferred for the introduction of the cracks to take place as a result of cooling from the temperature of brazing. During cooling from the temperature of brazing, a particularly advantageous temperature gradient is established and this brings about a local increase in the stresses, in the preferred case tensile stresses, in the coating material. This additionally results, due to the notch effect of the structuring, in crack formation and crack propagation along the structuring and thus in a deliberately introduced, largely predefined crack network in the coating material which preferably runs largely along the structuring.

As an alternative to joining of the coating material to the support element by means of brazing, it is also possible to effect such joining by adhesive bonding and curing of the adhesive at high temperatures. Curing of adhesives suitable for this purpose normally takes place at from about 120 to 250° C. The temperature gradients introduced during such a process step are thus comparatively small compared to a brazing step. Joining by adhesive bonding is particularly suitable for coating sources having very brittle coating materials and very high coefficients of thermal expansion compared to the material of the support element.

In addition to the abovementioned steps, a process according to the invention can additionally preferably comprise the following step:
particle blasting of the coating source

Particle blasting of the coating source is preferably carried out after joining to the surface of the coating material facing away from the support element. As blasting particles, it is possible to use abrasive or nonabrasive media. Particle blasting of the coating source can assist the formation of the cracks, with this being brought about by impingement of the blasting particles (e.g. sandblasting using α-alumina), which in turn increases the stresses in the coating material further. At the same time, a decrease in the elastic deformations which have arisen in the support element during production of the coating source can occur as a result of the aiding of crack formation and crack propagation in the coating material.

As an alternative to or in addition to a particle blasting treatment, a thermal treatment of the coating source can be carried out, for example by rapid cooling by means of liquid nitrogen. This can locally produce even higher temperature gradients in the coating material, which in turn increases the stresses which arise and further assists the formation of the cracks.

A process according to the invention for producing a coating source is particularly suitable for producing a coating source according to the invention as described above.

A process according to the invention has been found to be particularly advantageous for producing coating sources in which the thickness of the coating material is high compared to the support element. In the prior art, permanent bending of the support element instead of crack formation in the coating material occurs during production of the coating source in the case of coating materials which are too thick compared to the support element. It is presumed that in such cases the tensile stresses in the coating material are lower than the fracture stress of the coating material. Coating sources which have been deformed (bent) in this way can firstly not be installed correctly in a coating plant. Secondly, a coating source which has been deformed in this way would suddenly rupture when the critical stress is attained and in turn lead to disruption of the coating process due to the progressive removal of material during the coating process and the associated decrease in thickness of the coating material.

For economic reasons, the ratio X=d₂/(d₂+d₃) is made as high as technically possible, viz. the thickness of the coating material d₂ makes up a large proportion of the total thickness of the coating source d₁=d₂+d₃.

A process according to the invention for producing a coating source in which the ratio X=d₂/(d₂+d₃) of the thickness of the coating material d₂ to the sum d₂+d₃ of the thickness of the coating material d₂ and the thickness of the support element d₃ is greater than 0.5 has been found to be particularly advantageous. A maximum ratio X of 0.9 is appropriately even more preferred.

A process according to the invention for producing a coating source in which the ratio X=d₂/(d₂+d₃) of the thickness of the coating material d₂ to the sum d₂+d₃ of the thickness of the coating material d₂ and the thickness of the support element d₃ is greater than or equal to 0.6 has been found to be even more advantageous. A maximum ratio X of 0.85 is appropriately even more preferred.

Advantages and details and also particularly advantageous embodiments of the invention are illustrated in more detail by the following examples and figures.

### Example 1 (Not According to the Invention)

A coating source having a TiB₂ coating material which was joined by brazing to a back plate made of the material MoCu70/30 wt % was produced. The diameter of the coating source was 150 mm and the total thickness d₁ was 12 mm. The coating material had a thickness d₂ of 6 mm, and the back plate likewise had a thickness d₃ of 6 mm. The ratio X=d₂/(d₂+d₃) was thus 0.5. In this case, the coefficient of thermal expansion of the MoCu70/30 wt % back plate was, at 9.5 ppm/K (compared to 5.2 ppm/K for pure Mo), greater than that of the coating material of 7.3 ppm/K. Here, compressive stresses arise in the coating material during cooling from the temperature of brazing, so that no crack formation perpendicular to the surface of the coating material occurs and the coating material arches in the direction of the back plate. The compressive stresses in the coating material are in this case so high that spalling of fragments parallel to the surface of the coating source or of the coating material occurs due to generation of shear stresses.

### Example 2 (Not According to the Invention)

A coating source having a TiB₂ coating material which was joined by brazing to a thinner back plate made of Mo was produced. The diameter of the coating source was 150 mm and the total thickness d₁ was 16 mm. The coating material had a thickness d₂ of 10 mm, and the back plate had a thickness d₃ of 6 mm. The ratio X=d₂/(d₂+d₃) was thus 0.625. In this example, the tensile stresses arising as a result of cooling from the temperature of brazing were apparently so small that formation of cracks in the coating material did not occur. Instead, arching of the coating material in the direction of the back plate occurred.

### Example 3 (Not According to the Invention)

A coating source having a CrSiB coating material which was joined by brazing to a back plate made of Mo was produced. The diameter of the coating source was 150 mm and the total thickness d₁ was 12 mm. The coating material had a thickness d₂ of 6 mm, and the back plate had a thickness d₃ of 6 mm. The ratio X=d₂/(d₂+d₃) was thus 0.5. The CrSiB coating material is the brittle composition CrSiB 92/3/5 at %. Cracks arose perpendicular to the surface of the coating material as a result of cooling from the temperature of brazing.

### Example 4 (Not According to the Invention)

A coating source having a CrSiB coating material which was joined by brazing to a thinner back plate made of Mo was produced. The diameter of the coating source was 100 mm and the total thickness d₁ was 16 mm. The coating material had a thickness d₂ of 12 mm, and the back plate had a thickness d₃ of 4 mm.

The ratio X=d₂/(d₂+d₃) was thus 0.75. The CrSiB coating material is the brittle composition CrSiB 92/3/5 at %. No cracks were formed as a result of cooling from the temperature or brazing.

### Example 5 (According to the Invention)

A coating source having an MoSiB coating material which was joined by brazing to a back plate made of Mo was produced. The diameter of the coating source was 150 mm and the total thickness d₁ was 12 mm. The coating material had a thickness d₂ of 6 mm, and the back plate had a thickness d₃ of 6 mm. The ratio X=d₂/(d₂+d₃) was thus 0.5. The MoSiB coating material is the brittle composition MoSiB 50/30/20 at %. The coating material was provided with structuring by means of wire cutting before brazing. Cracks perpendicular to the surface of the coating material were formed as a result of cooling from the temperature of brazing. In addition to cracks along the structuring, cracks which form an irregular network are also present. No breaking-off of relatively small pieces of the coating material occurred.

### Example 6 (According to the Invention)

A coating source having a TiB₂ coating material which was joined by brazing to a back plate made of Mo was produced. The diameter of the coating source was 150 mm and the total thickness d₁ was 12 mm. The coating material had a thickness d₂ of 6 mm, and the back plate had a thickness d₃ of 6 mm. The ratio X=d₂/(d₂+d₃) was thus 0.5. The coating material was provided with structuring by means of wire cutting before brazing. Cracks perpendicular to the surface of the coating material were formed as a result of cooling from the temperature of brazing. These cracks run largely along the structuring. No breaking-off of relatively small pieces of the coating material occurred.

### Example 7 (According to the Invention)

A coating source having a TiB₂ coating material which was joined by brazing to a back plate made of Mo was produced. The diameter of the coating source was 150 mm and the total thickness d₁ was 12 mm. The coating material had a thickness d₂ of 8 mm, and the back plate had a thickness d₃ of 4 mm. The ratio X=d₂/(d₂+d₃) was thus 0.67. The coating material was provided with structuring by means of wire cutting before brazing. This structuring had been carried out by wire cutting using 1 mm deep cuts arranged at right angles to one another. Cracks perpendicular to the surface of the coating material were formed as a result of cooling from the temperature of brazing. These cracks run largely along the structuring. No breaking-off of relatively small pieces of the coating material occurred.

### Example 8 (According to the Invention)

A coating source having a TiB₂ coating material which was joined in the form of cylindrical rings to a tubular support element (support or carrier tube) made of Mo by brazing was produced. The diameter of the total of 5 TiB₂ rings was 116 mm on the outside and 91.5 mm on the inside, and the height (extension in the direction of the rotational axis) of the individual rings was 30 mm. The diameter of the Mo support tube was 91.45 mm on the outside and 76.1 mm on the inside. The total length of the Mo support tube was 200 mm. The coating material thus had a thickness of 12.25 mm and the support tube had a thickness of 7.67 mm. The ratio X=d₂/(d₂+d₃) was thus 0.62. The coating material was provided with structuring by means of wire cutting before brazing. This was carried out by wire cutting using 1 mm deep cuts arranged parallel to one another. Cracks perpendicular to the surface of the coating material were formed as a result of cooling from the temperature of brazing. These cracks run largely along the structuring. No breaking-off of relatively small pieces of the coating material occurred.

In addition to the examples, some simple calculations were carried out. These had the objective of determining the ratio X=d₂/(d₂+d₃) of the thickness of the coating material d₂ to the sum d₂+d₃ of the thickness of the coating material d₂ and the thickness of the support element d₃ above which structuring of the coating material is particularly advantageous in order to generate cracks according to the invention.

It is presumed that a prerequisite for the formation of cracks in the coating material is that the product of the tensile strength of the brittle coating material and its thickness d₂ is smaller than the product of the elastic limit and the thickness d₃ of the back plate. In this liming case, the two products are equivalent. Looking at the example of TiB₂ on Mo with the tensile strength of about 500 MPa for TiB₂ and the elastic limit of about 750 MPa for Mo, the limiting condition prevails, to a first rough approximation, when the thickness of the coating material makes up 60% of the total thickness d₁ of the coating source. In the case of thinner coating materials, a crack network can form even without structuring and in the case of thicker coating materials the back plate is elastically and/or plastically deformed or bent or it arches. For this reason, a crack network was formed in the CrSiB/Mo coating source having 6 mm of CrSiB on 6 mm of Mo of Example 3, while the TiB₂/Mo coating source having 10 mm of TiB₂ on 6 mm of Mo of Example 2 displayed no cracks in the TiB₂ and the Mo plate was bent. Structuring as, for example, in Example 7 enabled cracks to be introduced along the structuring, which is presumably attributable to a reduction in the load-bearing cross section (of the thickness) of the coating material or to a notch effect and local increases in the stress, or a combination thereof.

The figures show:

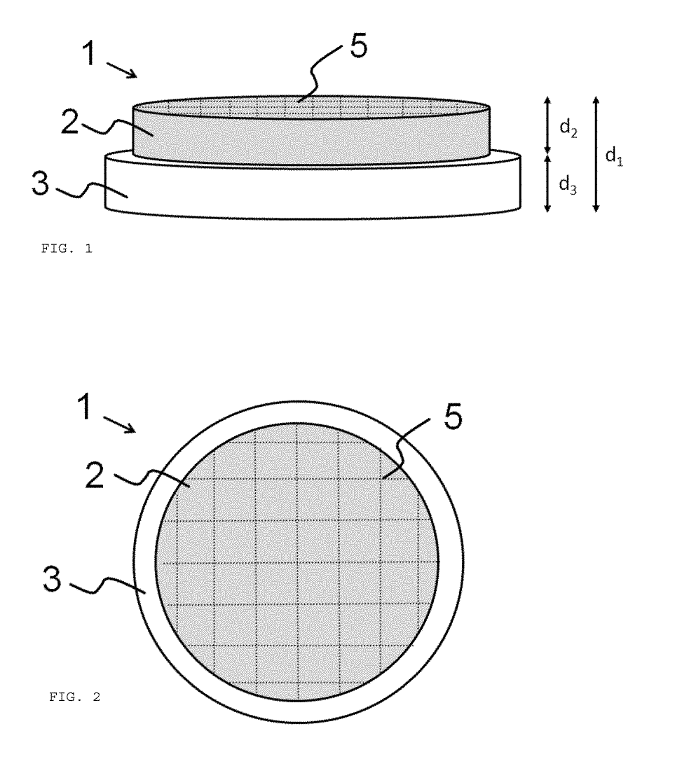

FIG. 1: Coating source (1) having a coating material (2), a support element (3) and structuring (5) before introduction of the cracks.

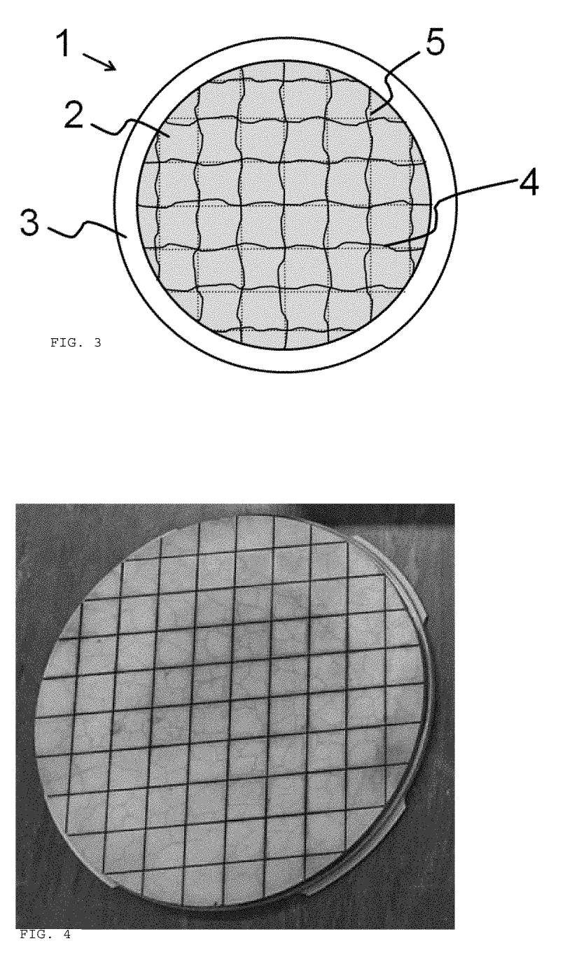

FIG. 2: Plan view of the coating source of FIG. 1.

FIG. 3: Plan view of a coating source (1) according to the invention after introduction of the cracks (4).

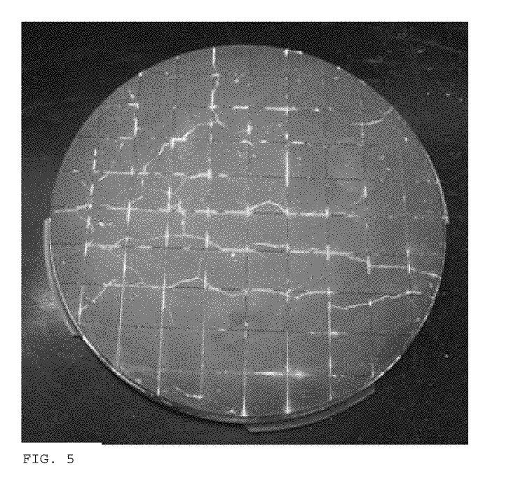

FIG. 4: Coating source having MoSiB coating material (Example 5) after brazing and cleaning with cracks formed.

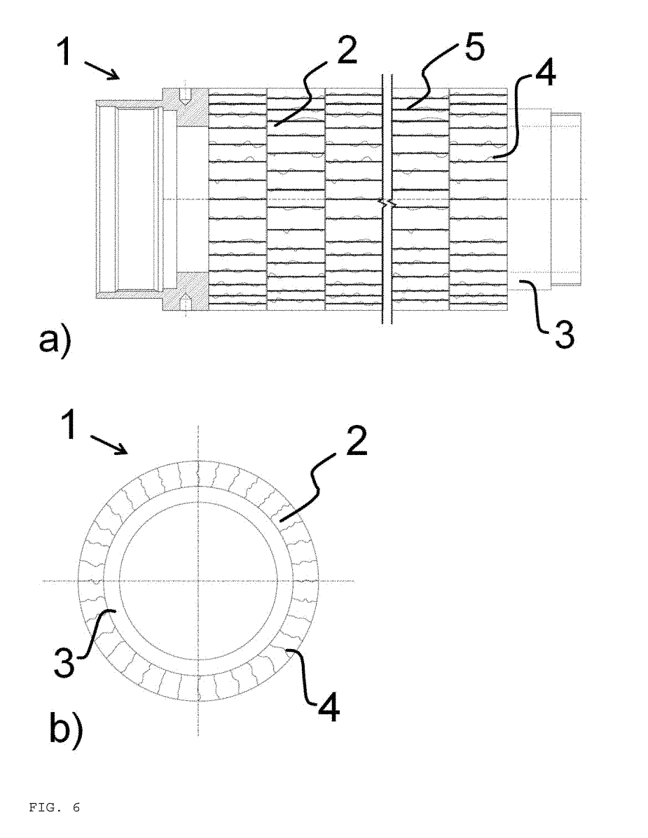

FIG. 5: Coating source having TiB₂ coating material (Example 6) brazed onto Mo back plate. Cracks made visible by dye penetration testing using fluorescent dye.

FIG. 6: Tubular coating source (1) having coating material (2), support or carrier tube (support element) (3) and structuring (5) after introduction of the cracks (4) in a) side view, in b) plan view.

FIG. 1 shows a coating source (1) for physical vapor deposition before introduction of the cracks. The coating source (1) has a coating material (2) and a support element (3). The coating material (2) is joined to the support element (3) at a surface of the coating material (2).

The coating material (2) has structuring (5). The structuring (5) consists of an arrangement of a first group of parallel linear depressions (shown as broken lines) and a second group of parallel linear depressions (shown as broken lines) which are arranged at right angles to the first group of parallel linear depressions.

FIG. 2 shows a plan view of the coating source of FIG. 1.

FIG. 3 shows a coating source according to the invention after introduction of the cracks (4). The cracks (4) run largely along the structuring (5).

FIG. 4 shows a coating source produced according to Example 5. It has an MoSiB coating material which was applied by means of brazing to a back plate made of Mo and subsequently cleaned. In addition to cracks along the structuring, there are also cracks which form an irregular network. No breaking-off of relatively small pieces of the coating material occurred.

FIG. 5 shows a coating source produced according to Example 6. It has a TiB₂ coating material which was applied by means of brazing to a Mo back plate. The cracks introduced were made visible by means of fluorescent dye in a dye penetration test.

FIG. 6 shows a tubular coating source (1). A side view of the tubular coating source (1) is shown in a), and a plan view in the direction of the rotational axis of the coating source (1) is shown in b). The coating material (2) is in this case made up of individual cylindrical rings, and the support element (3) is configured as support or carrier tube. The structuring (5) is formed on the lateral surface of the coating material (2), and the cracks (4) run largely along the structuring (5).

### LIST OF THE REFERENCE SYMBOLS USED

1 coating source
2 coating material
3 support element
4 cracks
5 structuring
d₁ total thickness of the coating source
d₂ thickness of the coating material
d₃ thickness of the support element

1-20. (canceled)

21. A coating source for physical vapor deposition, the coating source comprising:
a coating material being a brittle material and having cracks, said coating material having structuring on at least parts of a surface of said coating material; and
a support element joined to said coating material at a surface of said coating material.

22. The coating source according to claim 21, wherein said cracks run primarily along said structuring.

23. The coating source, according to claim 21, wherein a proportion of more than 50% of a total crack length of said cracks runs along said structuring.

24. The coating source according to claim 21, wherein said structuring is formed on a surface of said coating material averted from said support element.

25. The coating source according to claim 21, wherein said structuring comprises an arrangement of a first group of parallel linear depressions and a second group of parallel linear depressions, and wherein said second group of parallel linear depressions is oriented to enclose an angle of between 70° and 110° with said first group of parallel linear depressions.

26. The coating source according to claim 21, wherein said coating material has a coefficient of thermal expansion α₂ that is greater than a coefficient of thermal expansion α₃ of said support element.

27. The coating source according to claim 21, wherein said coating material is a material selected from the group consisting of TiB₂, SiC, B₄C, MoSiB and CrSiB.

28. The coating source according to claim 21, wherein said support element consists of a material selected from the group consisting of molybdenum, tungsten, tantalum, a molybdenum-based alloy, a tungsten-based alloy and a tantalum-based alloy.

29. The coating source according to claim 21, wherein said support element has an E modulus E₃ greater than or equal to 300 GPa.

30. The coating source according to claim 21, wherein said coating material has a thickness d₂, said support element has a thickness d₃, and wherein a ratio X=d₂/(d₂+d₃) of the thickness d₂ to a sum d₂+d₃ of the thickness d₂ and the thickness d₃ is greater than 0.5.

31. The coating source according to claim 30, wherein the ratio X=d₂/(d₂+d₃) is greater than or equal to 0.6.

32. The coating source according to claim 21, formed as a plate-shaped coating source or a tubular coating source.

33. A process for producing a coating source for physical vapor deposition, the process comprising the following steps:
providing a coating material being a brittle material;
structuring the coating material to produce structuring on at least a portion of a surface of the coating material;
providing a support element;
joining of the coating material to the support element; and
introducing cracks into the coating material.

34. The process according to claim 33, wherein the structuring step comprises effecting a process step selected from the group consisting of eroding, wire cutting, grinding or parting the coating material.

35. The process according to claim 33, wherein the structuring step comprises pressing the coating material with a profiled pressing tool.

36. The process according to claim 33, which comprises introducing the structuring on a surface of the coating material which, after joining to the support element, faces away from the support element.

37. The process according to claim 33, wherein the joining step comprises brazing at temperatures in a range from 400° C. to 950° C.

38. The process according to claim 33, wherein the step of introducing the cracks comprises cooling from an elevated temperature.

39. The process according to claim 38, wherein the joining step comprises brazing the coating material to the support element, and the step of introducing the cracks results from cooling the coating source from a brazing temperature.

40. The process according to claim 33, which further comprises a step of particle blasting the coating source.
